(19) United States
(12) Patent Application Publication
(10) Pub. No.: US 2026/0123539 A1
(43) Pub. Date: Apr. 30, 2026

(54) STACK STRUCTURE

(71) Applicant: APACECORE PTE. LTD., Hsinchu County (TW)

(72) Inventor: Yan-Lin Lu, Hsinchu County (TW)

(73) Assignee: APACECORE PTE. LTD., Hsinchu County (TW)

(21) Appl. No.: 19/080,912

(22) Filed: Mar. 16, 2025

(30) Foreign Application Priority Data
Oct. 28, 2024 (TW) 113141056

(51) Int. Cl. H01L 25/16; H01L 23/48; H01L 23/538; H10B 80/00; H10F 39/95

(52) U.S. Cl. CPC H10W 90/00; H10W 20/20; H10B 80/00; H10F 39/95; H10W 70/611; H10W 70/635

(57) ABSTRACT

A stack structure includes a substrate, a first memory layer, a logic chip, and a co-packaged optics. The first memory layer is disposed over the substrate. The logic die is disposed on and electrically connected to the first memory layer. The co-packaged optics is disposed on and electrically connected to the first memory layer.

### CROSS-REFERENCE TO RELATED APPLICATION

This application claims the priority benefit of Taiwan application serial no. 113141056, filed on Oct. 28, 2024. The entirety of the above-mentioned patent application is hereby incorporated by reference herein and made a part of this specification.

### BACKGROUND

### Technical Field

The disclosure relates to a structure, and more particularly, to a stack structure.

### Description of Related Art

With the rapid development of artificial intelligence (AI) technology, the demand for high-performance and low-latency computing is increasing. Artificial intelligence applications, such as deep learning and machine learning, require high-speed processing and transmission of large amounts of data for efficient training and inference. In order to be suitable for high-efficiency computing applications, it is necessary to improve the signal transmission speed of current integrated circuit packages and reduce power consumption thereof.

### SUMMARY

The disclosure provides a stack structure, which has an improved data access speed and overall performance and may reduce power consumption.

A stack structure in the disclosure includes a substrate, a first memory layer, a logic chip, and a co-packaged optics. The first memory layer is disposed over the substrate. The logic chip is disposed on the first memory layer, and is electrically connected to the first memory layer. The co-packaged optics is disposed on the first memory layer, and is electrically connected to the first memory layer.

In an embodiment of the disclosure, the logic chip and the co-packaged optics are disposed side by side in a horizontal direction.

In an embodiment of the disclosure, the first memory layer includes a single memory chip, and the co-packaged optics and the logic chip are disposed on the memory chip, and are electrically connected to the memory chip.

In an embodiment of the disclosure, a width of the memory chip is greater than a width of the co-packaged optics and a width of the logic chip.

In an embodiment of the disclosure, the first memory layer includes a first memory chip and a second memory chip, and the first memory chip and the second memory chip are spaced apart in a horizontal direction. The co-packaged optics is disposed on the first memory chip, and is electrically connected to the first memory chip, and the logic chip is disposed on the second memory chip, and is electrically connected to the second memory chip.

In an embodiment of the disclosure, the stack structure further includes a second memory layer disposed on the first memory layer. The second memory layer is located between the first memory layer and the co-packaged optics, and the co-packaged optics is electrically connected to the first memory layer through the second memory layer.

In an embodiment of the disclosure, the first memory layer is configured to receive a data request from the logic chip, and control and manage access to a memory cell of the second memory layer.

In an embodiment of the disclosure, the co-packaged optics is configured to receive an optical signal from an external component and convert the optical signal into an electrical signal. The electrical signal is transmitted to the logic chip through the first memory layer and the second memory layer. The logic chip is configured to perform logic computing and data processing. In a process of performing the logic computing and the data processing, the logic chip sends the data request to the first memory layer, and the first memory layer allocates data to the second memory layer for access. A computation result of the logic chip is transmitted to the co-packaged optics through the first memory layer.

In an embodiment of the disclosure, the first memory layer includes a first memory chip and a second memory chip, and the first memory chip and the second memory chip are spaced apart in a horizontal direction. The second memory layer includes a third memory chip and a fourth memory chip. The first memory chip and the second memory chip are spaced apart in the horizontal direction. The first memory chip and the third memory chip are stacked in a vertical direction, and the second memory chip and the fourth memory chip are stacked in the vertical direction. The horizontal direction is perpendicular to the vertical direction.

In an embodiment of the disclosure, the co-packaged optics overlaps the first memory chip and the third memory chip in the vertical direction, and the logic chip overlaps the second memory chip and the fourth memory chip in the vertical direction.

In an embodiment of the disclosure, the stack structure further includes an interposer disposed between the substrate and the first memory layer.

In an embodiment of the disclosure, the co-packaged optics is electrically connected to the interposer through a through substrate via of the first memory layer.

In an embodiment of the disclosure, the first memory layer includes a static random-access memory.

In an embodiment of the disclosure, the co-packaged optics is configured to receive an optical signal from an external component and convert the optical signal into an electrical signal. The electrical signal is transmitted to the logic chip through the first memory layer. The logic chip is configured to perform logic computing and data processing. In a process of performing the logic computing and the data processing, data is written from the logic chip to the first memory layer or read from the first memory layer to the logic chip. A computation result of the logic chip is transmitted to the co-packaged optics through the first memory layer.

Based on the above, the stack structure in the disclosure includes the logic chip and the co-packaged optics stacked on the memory layer, which may shorten the distance of data transmission, thereby improving the data access speed and the overall performance and reducing the power consumption. In addition, tightly stacked on the memory layer, the logic chip and the co-packaged optics may facilitate the development of the miniaturization of the product.

### BRIEF DESCRIPTION OF THE DRAWINGS

FIG. 1 is a schematic cross-sectional view of a stack structure according to an embodiment of the disclosure.

FIG. 2 is a schematic top view of a stack structure according to an embodiment of the disclosure.

FIGS. 3A to 3E are schematic views of a co-packaged optics according to some embodiments of the disclosure.

FIG. 4 is a schematic view of an optical transceiving module according to an embodiment of the disclosure.

FIG. 5 is a schematic view of the stack structure in FIG. 1 connected to an external component.

FIG. 6 is a schematic view of a data stream in FIG. 5.

FIG. 7 is a schematic cross-sectional view of a stack structure according to another embodiment of the disclosure.

FIG. 8 is a schematic cross-sectional view of a stack structure according to another embodiment of the disclosure.

FIG. 9 is a schematic view of a data stream of the stack structure in FIG. 8 connected to an external component.

FIG. 10 is a schematic cross-sectional view of a stack structure according to another embodiment of the disclosure.

### DETAILED DESCRIPTION OF DISCLOSED EMBODIMENTS

In the accompany drawings, for the sake of clarity, thicknesses of layers, films, panels, regions, etc., are enlarged. Throughout the specification, the same reference numerals refer to the same elements. It should be understood that when an element such as a layer, a film, a region, or a substrate is described as being “on” or “connected to” another element, it may be directly on or connected to the another element, or there may be an intervening element. In contrast, when an element is described as being “directly on” or “directly connected to” another element, there are no intervening elements. As used herein, “connected” may refer to physical and/or electrical connection. Furthermore, “electrical connection” or “coupling” may mean the presence of other elements between the two elements.

It should be understood that, although terms such as “first” and “second” may be used herein to describe various elements, components, regions, layers, and/or portions, the elements, components, regions, layers, and/or portions should not be limited by the terms. The terms are only used to distinguish one element, component, region, layer, or portion from another element, component, region, layer, or portion. Thus, a “first element”, “component”, “region”, “layer”, or “section” discussed below may be referred to as a second element, component, region, layer, or portion without departing from the teachings herein.

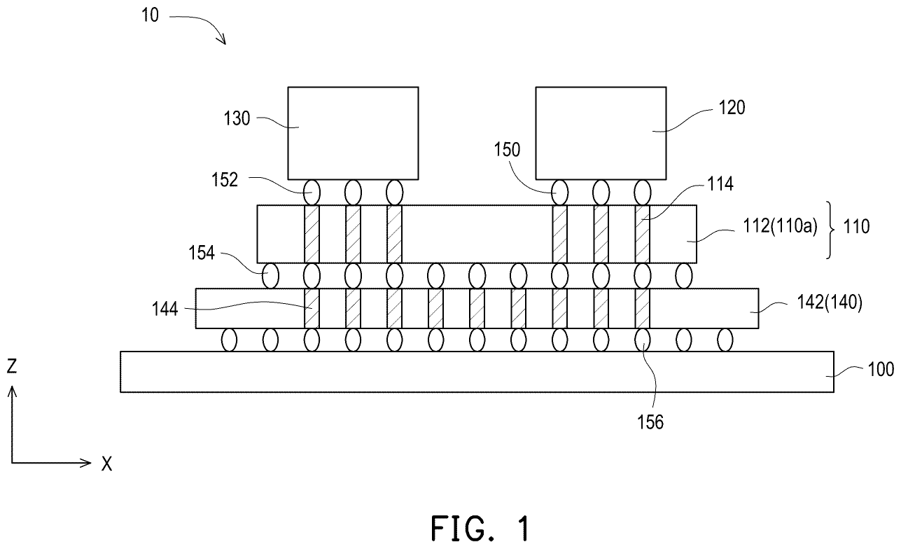

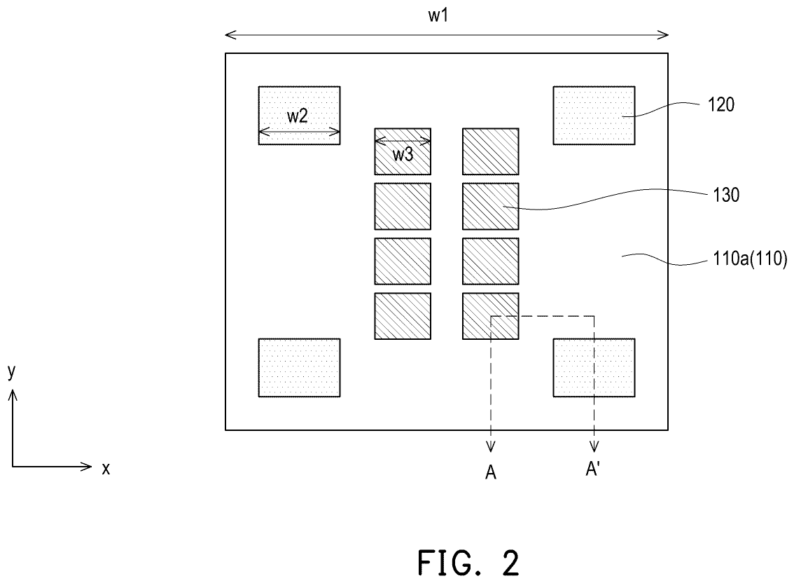

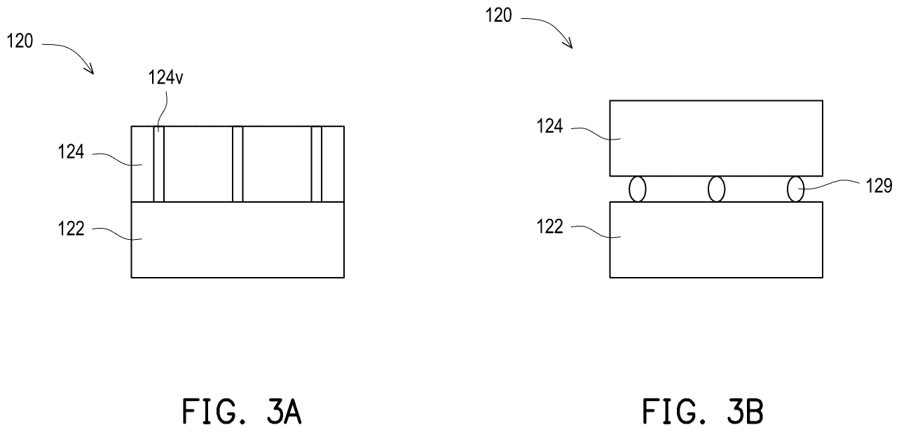

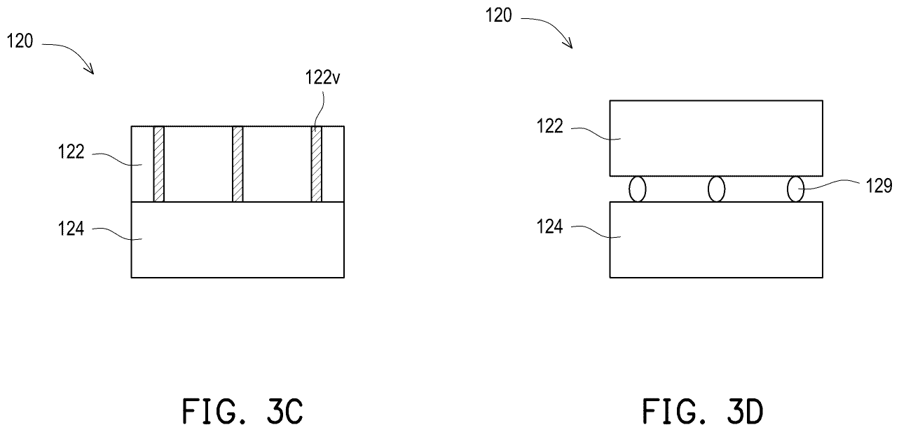

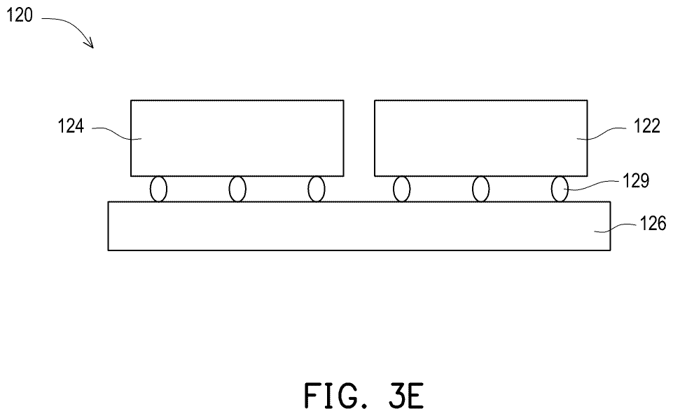

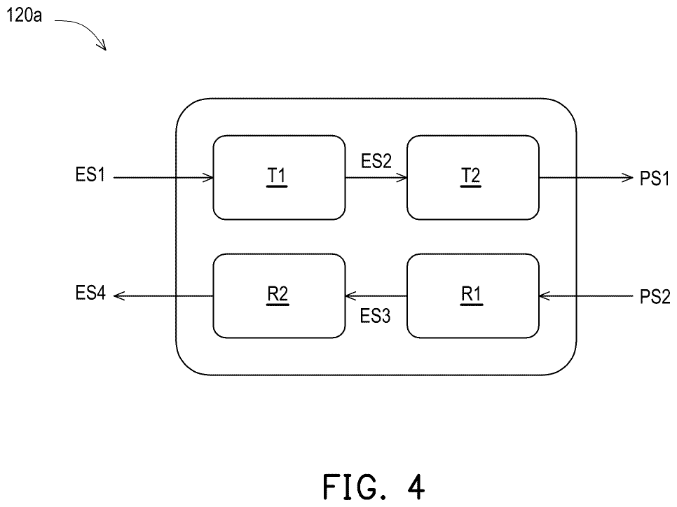

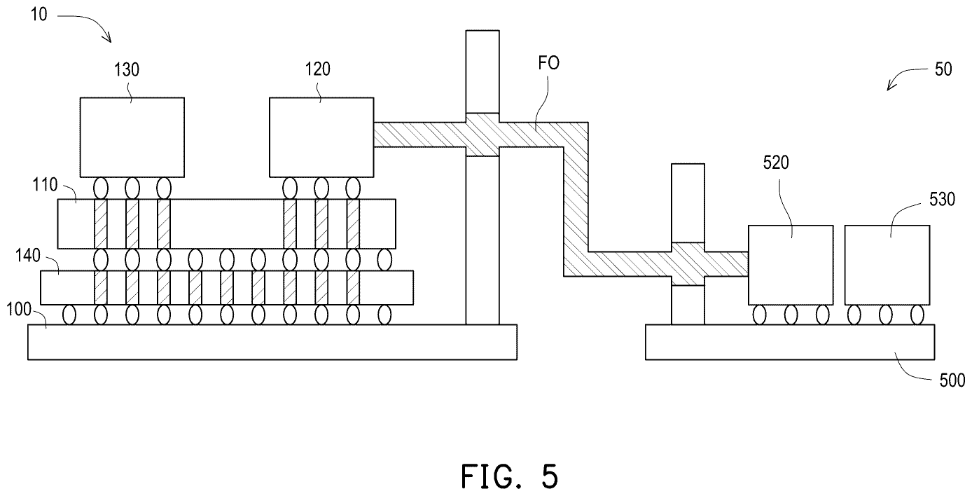

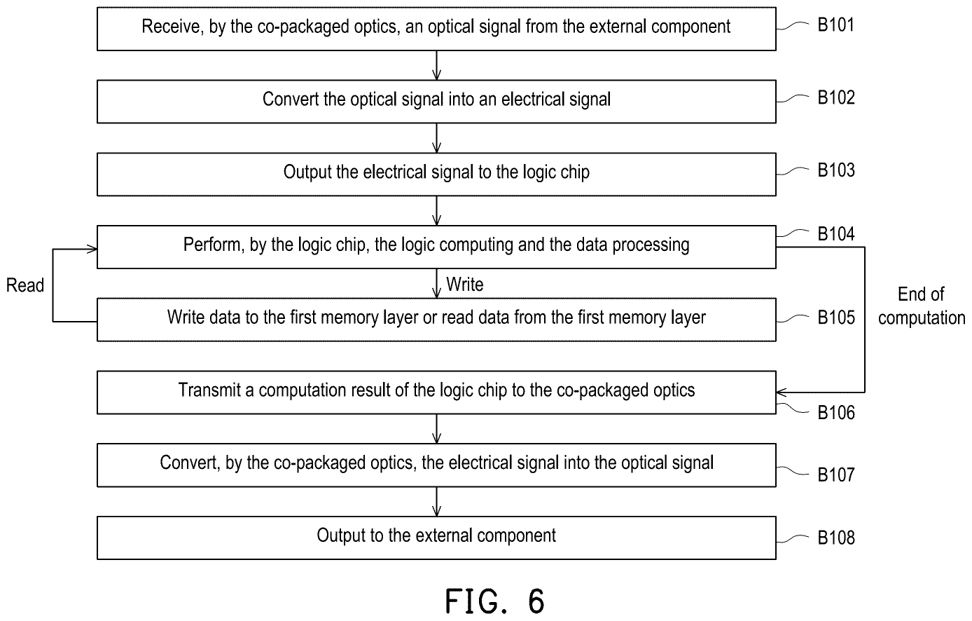

FIG. 1 is a schematic cross-sectional view of a stack structure according to an embodiment of the disclosure. FIG. 2 is a schematic top view of a stack structure according to an embodiment of the disclosure. FIGS. 3A to 3E are schematic views of a co-packaged optics according to some embodiments of the disclosure. FIG. 4 is a schematic view of an optical transceiving module according to an embodiment of the disclosure. FIG. 5 is a schematic view of a stack structure 10 in FIG. 1 connected to an external component 50. FIG. 6 is a schematic view of a data stream in FIG. 5. FIG. 1 may be a schematic cross-sectional view cut along a section line A-A′ in FIG. 2. For clarity of illustration, only a first memory layer 110, a co-packaged optics 120, and a logic chip 130 are shown in FIG. 2, and other components are omitted. The omitted parts may be understood with reference to FIG. 1.

Referring to FIGS. 1 and 2, the stack structure 10 includes a substrate 100, the first memory layer 110, the co-packaged optics 120, and the logic chip 130. In this embodiment, the stack structure 10 further includes an interposer 140.

The substrate 100 may be a circuit substrate, which includes multiple alternately stacked insulating layers (not shown) and conductive layers (not shown) to provide electrical connections and mechanical support for a structure stacked thereon.

The first memory layer 110 is disposed over the substrate 100, and is configured to provide storage space for fast access. In some embodiments, the first memory layer 110 may include a static random-access memory (SRAM). In some embodiments, the first memory layer 110 includes a single memory chip (e.g., a first memory chip 110a), but the disclosure is not limited thereto. In other embodiments, the first memory layer 110 may include multiple memory chips arranged side by side in a horizontal direction. Herein, the horizontal direction refers to a direction parallel to a top surface of the substrate 100, such as an x direction or a y direction.

In some embodiments, the first memory chip 110a may include multiple memory cells (not shown) arranged in an array on a semiconductor substrate 112, and driving circuits (not shown) electrically connected to the memory cells. In some embodiments, the first memory chip 110a may further include a through substrate via 114 to be vertically connected to circuits on two opposite sides of the interposer 140 to shorten a signal transmission path.

The co-packaged optics 120 is disposed on the first memory layer 110, and is electrically connected to the first memory layer 110. The co-packaged optics 120 is configured to convert an optoelectronic signal, so that an optical signal may be converted into an electrical signal through the co-packaged optics 120, or the electrical signal may be converted into the optical signal through the co-packaged optics 120. In some embodiments, the co-packaged optics 120 may be electrically connected to the first memory layer 110 through the conductive connecting member 150. The conductive connecting member 150 may include, for example, a micro bump, a solder ball, or other suitable conductive connection materials, but the disclosure is not limited thereto.

In some embodiments, the co-packaged optics 120 may include an integrated circuit (EIC) die 122 and an integrated optics (PIC) die 124. An arrangement of the integrated circuit (EIC) die 122 and the integrated optics (PIC) die 124 may be shown in FIGS. 3A to 3E. For example, the integrated circuit die 122 and the integrated optics die 124 may be stacked in a vertical direction z (as shown in FIGS. 3A to 3D), or arranged side by side in the horizontal direction (as shown in FIG. 3E).

In some embodiments, as shown in FIGS. 3A and 3B, the integrated optics die 124 may be disposed on the integrated circuit die 122. In FIG. 3A, the integrated optics die 124 may be tightly bonded to the integrated circuit die 122 through hybrid bonding to facilitate efficient signal transmission and miniaturized packaging. In some embodiments, the integrated optics die 124 may have a through oxide via (TOV) 124v, and the integrated optics die 124 may be optically interconnected to the integrated circuit die 122 through the through oxide via 124v. In FIG. 3B, the integrated optics die 124 is bonded to the integrated circuit die 122 using the flip-chip bonding technology. In some embodiments, the integrated optics die 124 may be electrically connected to the integrated circuit die 122 through a conductive connecting member 129. The conductive connecting member 129 may include, for example, a micro bump, a solder ball, or other suitable conductive connection materials. In the embodiment of FIGS. 3A and 3B, the integrated circuit die 122 of the co-packaged optics 120 is located between the integrated optics die 124 and the first memory layer 110.

In some embodiments, as shown in FIGS. 3C and 3D, the integrated circuit die 122 may also be disposed on the integrated optics die 124. In FIG. 3C, the integrated circuit die 122 may be tightly bonded to the integrated optics die 124 through the hybrid bonding to facilitate the efficient signal transmission and the miniaturized packaging. In some embodiments, the integrated circuit die 122 may have a through silicon via (TSV) 122v, and the integrated circuit die 122 may be electrically connected to the integrated optics die 124 through the through silicon via 122v. In FIG. 3D, the integrated circuit die 122 is bonded to the integrated optics die 124 using the flip-chip bonding technology. In some embodiments, similar to FIG. 3B, the integrated circuit die 122 may be electrically connected to the integrated optics die 124 through the conductive connecting member 129. In the embodiment of FIGS. 3C and 3D, the integrated optics die 124 of the co-packaged optics 120 is located between the integrated circuit die 122 and the first memory layer 110.

In some embodiments, as shown in FIG. 3E, the integrated circuit die 122 and the integrated optics die 124 are disposed on an interposer 126, and the integrated circuit die 122 and the integrated optics die 124 are arranged side by side. The interposer 126 includes, for example, multiple conducting wire layers to provide electrical interconnection between the integrated circuit die 122 and the integrated optics die 124 in the horizontal direction, so that the integrated circuit die 122 may be electrically connected to the integrated optics die 124 through the interposer 126. In this way, signal delay may be reduced while helping improve heat dissipation. In terms of application, in the embodiment of FIG. 3E, the integrated circuit die 122 and the integrated optics die 124 may be designed or updated independently, thus facilitating modular design without redesigning the entire co-packaged optics 120. In some embodiments, the integrated circuit die 122 and the integrated optics die 124 may be bonded to the interposer 126 using the flip-chip bonding technology, and may be electrically connected to the interposer 126 through the conductive connecting member 129. However, the disclosure is not limited thereto. In the embodiment of FIG. 3E, the interposer 126 of the co-packaged optics 120 is located between the integrated circuit die 122 and the integrated optics die 124 and the first memory layer 110.

In some embodiments, the co-packaged optics 120 may include an optical transceiving module 120a, which is configured to receive or transmit the optical signal and perform conversion of the optoelectronic signal. In some embodiments, the optical transceiving module 120a may include a laser driver T1, a transmitter optical sub-assembly (TOSA) T2, a receiver optical sub-assembly (ROSA) R1, and an amplifier R2, as shown in FIG. 4. From the perspective of transmitting the optical signal, an electrical signal ES1 from the stack structure 10 (e.g., the first memory layer 110) may be input to the laser driver T1, and then the laser driver T1 receives the electrical signal ES1 to be converted into a current that controls a laser diode (not shown), and drives the laser diode to emit an electrical signal ES2 to the transmitter optical sub-assembly T2. The transmitter optical sub-assembly T2 converts the electrical signal ES2 output by the laser driver T1 into an optical signal PS1. The transmitter optical sub-assembly T2 may then output the optical signal PS1 to the outside through optical fibers (not shown) or other optical transmission devices. From the perspective of receiving the optical signal, an optical signal PS2 may enter the receiver optical sub-assembly R1 from the outside through the optical fibers (not shown). The receiver optical sub-assembly R1 may convert the optical signal PS2 into an electrical signal ES3. The electrical signal ES3 may enter the amplifier R2 to amplify the electrical signal ES3 into an electrical signal ES4 to be output to the stack structure 10.

In some embodiments, the transmitter optical sub-assembly T2 and the receiver optical sub-assembly R1 may be disposed in the integrated optics die 124, and the laser driver T1 and the amplifier R2 may be disposed in the integrated circuit die 122.

In some embodiments, the logic chip 130 may be disposed on the first memory layer 110 and be electrically connected to the first memory layer 110. The logic chip 130 is configured to perform logic computing and data processing. In some embodiments, the logic chip 130 may include multiple transistors, logic circuits, etc. to perform computing and control tasks. In some embodiments, the logic chip 130 may be a central processing unit (CPU) chip, a graphics processing unit (GPU) chip, or other suitable chips. In some embodiments, the logic chip 130 may be electrically connected to the first memory layer 110 through a conductive connecting member 152. The conductive connecting member 152 may include, for example, a micro bump, a solder ball, or other suitable conductive connection materials, but the disclosure is not limited thereto.

In some embodiments, the logic chip 130 and the co-packaged optics 120 are disposed side by side on the first memory layer 110 in the horizontal direction (e.g., the x direction) and are spaced apart from each other. In this way, the first memory layer 110 and the co-packaged optics 120 may be closely stacked with the logic chip 130 to facilitate miniaturization of a product, and a distance of data transmission may be shortened due to the close stacking, thereby improving a data access speed and overall performance and reducing power consumption.

In some embodiments, the logic chip 130 and co-packaged optics 120 do not overlap in the vertical direction z.

In some embodiments, the logic chip 130 and the co-packaged optics 120 are disposed on the same memory chip (e.g., the first memory chip 110a) of the first memory layer 110. Therefore, in some embodiments, the logic chip 130 may be electrically connected to the co-packaged optics 120 through the first memory chip 110a. However, the disclosure is not limited thereto. In other embodiments, the logic chip 130 and the co-packaged optics 120 may be disposed on different memory chips of the first memory layer 110.

In some embodiments, a size (e.g., a length or a width) of the first memory chip 110a is greater than a size of the co-packaged optics 120 and a size of the logic chip 130. For example, as shown in FIG. 2, a width w1 of the first memory chip 110a is greater than a width w2 of the co-packaged optics 120 and a width w3 of the logic chip 130. In some embodiments, the width w2 of the co-packaged optics 120 is greater than the width w3 of the logic chip 130, but the disclosure is not limited thereto. The width w2 of the co-packaged optics 120 may also be less than or equal to the width w3 of the logic chip 130.

In some embodiments, the co-packaged optics 120 may be disposed around the logic chip 130. In some embodiments, the logic chips 130 may be arrayed in an array in a central portion of the first memory chip 110a, and the multiple co-packaged optics 120 are arranged in a peripheral portion of the first memory chip 110a to surround the logic chips 130. FIG. 2 schematically shows four co-packaged optics 120 and eight logic chips 130, but is not intended to limit the disclosure. The number and arrangement of the co-packaged optics 120 and the logic chip 130 may be adjusted according to actual requirements.

In some embodiments, the interposer 140 may be disposed between the substrate 100 and the first memory layer 110. The interposer 140 is configured to provide signal connections between the co-packaged optics 120 and the logic chip 130 and power distribution between the substrate 100 and the logic chip 130, the co-packaged optics 120, and/or the first memory layer 110.

In some embodiments, the interposer 140 may include a substrate 142 (e.g., a silicon substrate, a dielectric substrate, or other suitable substrates) and a high-density conductive layer (not shown). The high-density conductive layer is disposed on the substrate 142. In some embodiments, the interposer 140 may further include a through substrate via 144 to be vertically connected to the circuits on the two opposite sides of the interposer 140 to shorten the signal transmission path.

In some embodiments, the interposer 140 may be electrically connected to the first memory layer 110 through a conductive connecting member 154 and electrically connected to the substrate 100 through a conductive connecting member 156. For example, the conductive connecting members 154 and 156 may respectively include micro bumps, solder balls, or other suitable conductive connection materials, but the disclosure is not limited thereto.

Referring to FIG. 5, the stack structure 10 may perform high-speed communication with the external component 50 through the co-packaged optics 120. For example, the external component 50 may include a substrate 500, a co-packaged optics 520, and a logic chip 530. The co-packaged optics 520 and the logic chip 530 may be disposed side by side on the substrate 500 and electrically connected to the substrate 500. The co-packaged optics 120 of the stack structure 10 and the co-packaged optics 520 of the external component 50 may perform optical communication through optical fibers FO to achieve high-speed, low-latency, and low-loss communication quality, thereby facilitating long-distance signal transmission.

In some embodiments, a data stream between the stack structure 10 and the external component 50 may be as shown in FIG. 6. The co-packaged optics 120 of the stack structure 10 receives an optical signal from the external component 50 (corresponding to a block B101), and converts the optical signal into an electrical signal (corresponding to a block B102). The electrical signal is then output to the logic chip 130 (corresponding to a block B103). For example, the electrical signal may be transmitted to the interposer 140 through a portion of the first memory layer 110 corresponding to the co-packaged optics 120 (e.g., the through substrate via 114 of the first memory chip 110a), and may be then transmitted from the interposer 140 to the logic chip 130 through a portion of the first memory layer 110 corresponding to the logic chip 130 (e.g., the through substrate via 114 of the first memory chip 110a). In addition, the electrical signal may be directly transmitted to the logic chip 130 through the first memory layer 110, but the disclosure is not limited thereto. Then, the logic chip 130 performs the logic computing and the data processing (corresponding to a block B104). In a process of performing the logic computing and the data processing, the logic chip 130 may write data to the first memory layer 110 or read data from the first memory layer 110 as required (corresponds to a block B105). Afterwards, a computation result of the logic chip 130 is transmitted to the co-packaged optics 120 (corresponding to a block B106). For example, the computation result of the logic chip 130 may be transmitted to the interposer 140 through the portion of the first memory layer 110 corresponding to the logic chip 130, and then transmitted from the interposer 140 to the co-packaged optics 120 through the portion of the first memory layer 110 corresponding to the co-packaged optics 120. Then, the electrical signal is converted into the optical signal by the co-packaged optics 120 (corresponding to a block B107), and then is output to the external component 50 (corresponding to a block B108). In this way, the data processing may be concentrated on the logic chip 130, so that the first memory layer 110 focuses on high-speed access to data, achieving professional division of labor to improve operational efficiency and increase flexibility and reliability.

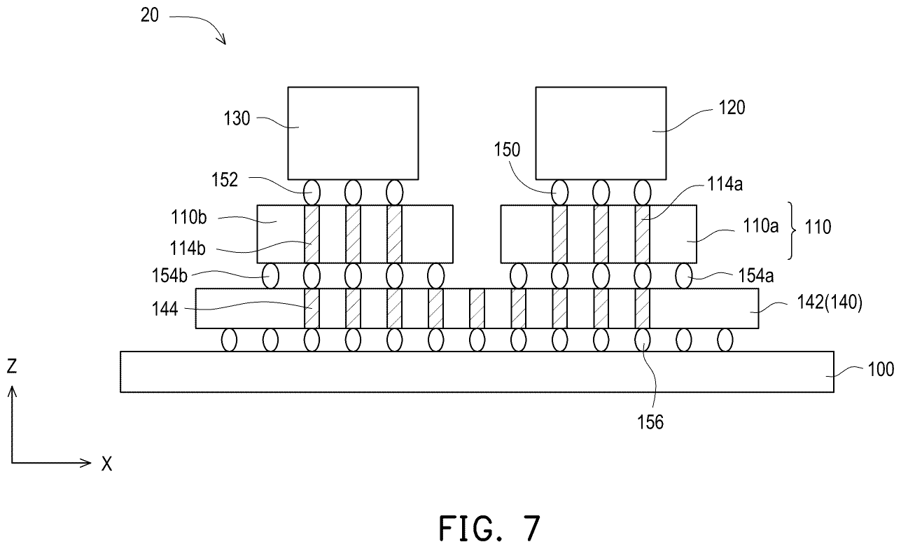

FIG. 7 is a schematic cross-sectional view of a stack structure according to another embodiment of the disclosure. It is noted that some of the reference numerals and descriptions in FIG. 1 will apply to FIG. 7. The same reference numerals will represent the same or similar components and the descriptions of the same technical contents will be omitted. Reference may be made to the above embodiment for the omitted descriptions, which will not be repeated in the following embodiments.

Referring to FIG. 7, a difference between this embodiment and the embodiment in FIG. 1 is that the co-packaged optics 120 and the logic chip 130 of a stack structure 20 are respectively disposed on different memory chips in the first memory layer 110. For example, the first memory layer 110 may include the first memory chip 110a and a second memory chip 110b. The first memory chip 110a and the second memory chip 110b are spaced apart in the horizontal direction (e.g., the x direction). That is, the first memory chip 110a and the second memory chip 110b do not overlap in the vertical direction z. The co-packaged optics 120 may be physically and electrically connected to the first memory chip 110a through the conductive connecting member 150, and the logic chip 130 may be physically and electrically connected to the second memory chip 110b through the conductive connecting member 152.

In some embodiments, the co-packaged optics 120 overlaps the first memory chip 110a in the vertical direction z, and the logic chip 130 overlaps the second memory chip 110b in the vertical direction z. Since the co-packaged optics 120 and the logic chip 130 are respectively disposed on different memory chips, the components on different memory chips may be designed independently, which is conducive to modularization of a system and facilitates system updates and upgrades, and the memory chip may also be flexibly disposed according to requirements of the components disposed thereon to meet different application scenarios.

In some embodiments, the first memory chip 110a and the second memory chip 110b may be electrically connected to the interposer 140 through conductive connecting members 154a and 154b respectively. That is to say, the first memory chip 110a may be electrically connected to the second memory chip 110b through the interposer 140. Materials of the conductive connecting members 154a and 154b may be similar to that of the conductive connecting member 154.

In some embodiments, the stack structure 20 may perform the high-speed communication with the external component 50 through the co-packaged optics 120, similar to that shown in FIG. 5. However, the stack structure 10 in FIG. 5 is replaced with the stack structure 20 in this embodiment. The co-packaged optics 120 of the stack structure 20 and the co-packaged optics 520 of the external component 50 may perform the optical communication through the optical fibers FO to achieve the high-speed, low-latency, and low-loss communication quality, thereby facilitating the long-distance signal transmission.

In some embodiments, a data stream between the stack structure 20 and the external component 50 may be similar to that shown in FIG. 6. However, when the stack structure 20 transmits the electrical signal to the logic chip 130, the electrical signal is transmitted to the interposer 140 through a through substrate via 114a of the first memory chip 110a, and then transmitted from the interposer 140 to the logic chip 130 through a through substrate via 114b of the second memory chip 110b. On the contrary, when the stack structure 20 transmits the computation result of the logic chip 130 to the co-packaged optics 120, the computation result is transmitted to the interposer 140 through the second memory chip 110b, and then transmitted from the interposer 140 to the co-packaged optics 120 through the first memory chip 110a.

It should be understood that FIG. 7 schematically shows one co-packaged optics 120 disposed on the first memory chip 110a and one logic chip 130 disposed on the second memory chip 110b, but is not intended to limit the disclosure. One or more co-packaged optics 120 and/or one or more logic chips 130 may be respectively disposed on the first memory chip 110a and the second memory chip 110b according to the actual requirements. In addition, the number of memory chips included in the first memory layer may be adjusted according to the actual requirements, and the disclosure is not limited thereto.

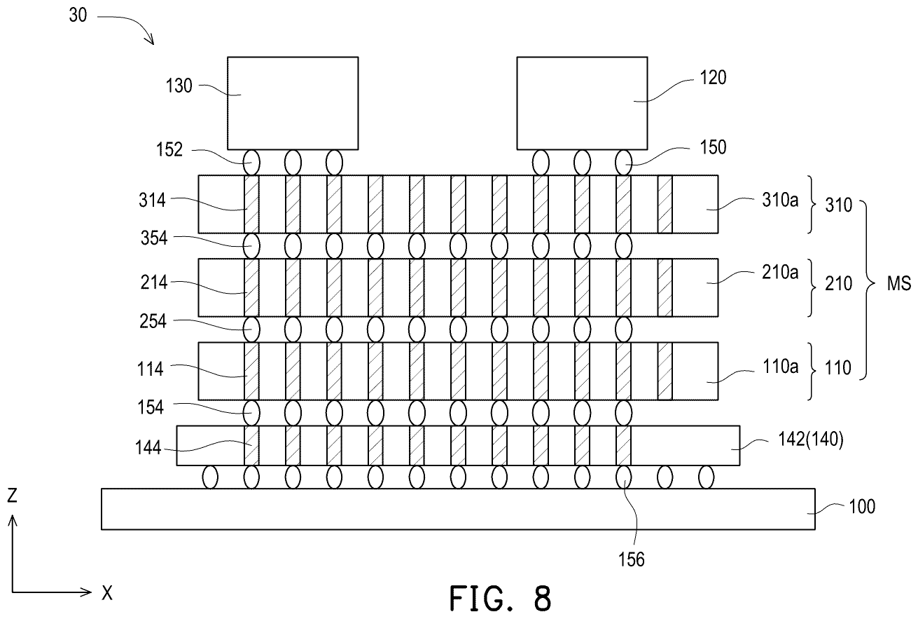

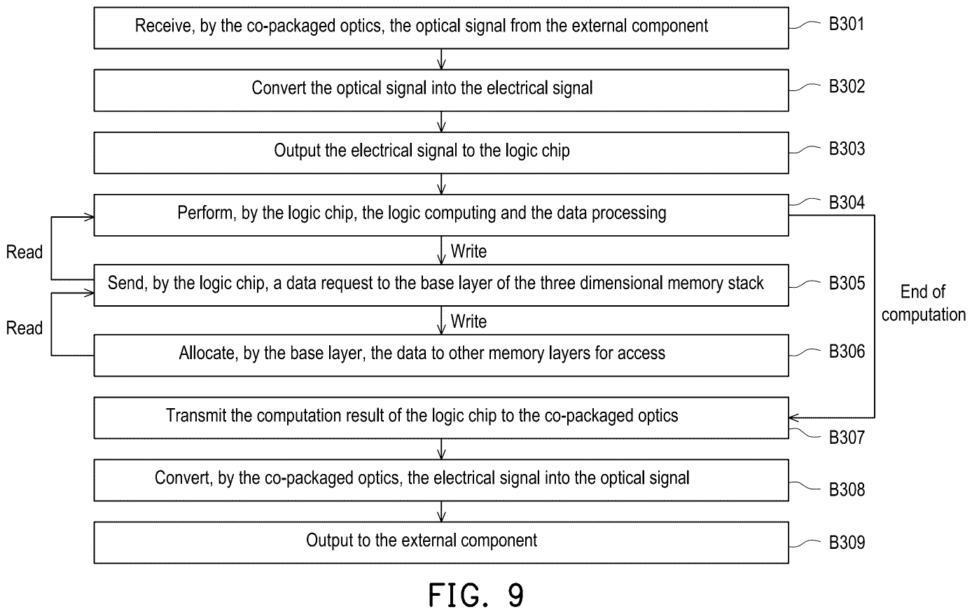

FIG. 8 is a schematic cross-sectional view of a stack structure according to another embodiment of the disclosure. FIG. 9 is a schematic view of a data stream of the stack structure in FIG. 8 connected to an external component. It is noted that some of the reference numerals and descriptions in FIG. 1 will apply to FIG. 8. The same reference numerals will represent the same or similar components and the descriptions of the same technical contents will be omitted. Reference may be made to the above embodiment for the omitted descriptions, which will not be repeated in the following embodiments.

Referring to FIG. 8, a difference between this embodiment and the embodiment in FIG. 1 is that a stack structure 30 includes multiple memory layers stacked sequentially in the vertical direction z, such as the first memory layer 110, a second memory layer 210, and a third memory layer 310. The first memory layer 110, the second memory layer 210, and the third memory layer 310 may form a three dimensional memory stack MS to increase storage capacity. The three dimensional memory stack MS may be located between the co-packaged optics 120, the logic chip 130, and the interposer 140, and is electrically connected to the co-packaged optics 120, the logic chip 130, and the interposer 140.

In some embodiments, the second memory layer 210 may be electrically connected to the first memory layer 110 through a conductive connecting member 254, and the third memory layer 310 may be electrically connected to the second memory layer 210 through a conductive connecting member 354. Materials of the conductive connecting member 254 and the conductive connecting member 354 may be similar to that of the conductive connector 154.

In some embodiments, the first memory layer 110, the second memory layer 210, and the third memory layer 310 may each include multiple through substrate vias 114, 214, and 314 to provide circuit connections in the vertical direction z to shorten the signal transmission path.

In some embodiments, each of the memory layers (e.g., the first memory layer 110, the second memory layer 210, the third memory layer 310) of the three dimensional memory stack MS each includes a single memory chip (e.g., memory chips 110a, 210a, and 310a). The memory chips 110a, 210a, and 310a are stacked on each other in the vertical direction z. In some embodiments, the logic chip 130 and the co-packaged optics 120 are disposed on the topmost memory chip (e.g., the memory chip 310a) of the three dimensional memory stack MS. That is to say, the logic chip 130 and the co-packaged optics 120 are disposed on the same memory chip. However, the disclosure is not limited thereto. In other embodiments, the logic chip 130 and the co-packaged optics 120 may be disposed on different memory chips.

In some embodiments, the bottommost memory layer (i.e., the first memory layer 110) of the three dimensional memory stack MS is a base layer of the three dimensional memory stack MS, which may be configured to control and manage operation of the three dimensional memory stack MS to allocate data from the logic chip 130 to memory cells of the memory layers for access, so that other memory layers (e.g., the second memory layer 210 and the third memory layer 310) focus on data access to achieve efficient data access and management of the three dimensional memory stack MS.

In some embodiments, the stack structure 30 may perform the high-speed communication with the external component 50 through the co-packaged optics 120, similar to that shown in FIG. 5. However, the stack structure 10 in FIG. 5 is replaced with the stack structure 30 in this embodiment. The co-packaged optics 120 of the stack structure 30 and the co-packaged optics 520 of the external component 50 may perform the optical communication through the optical fibers FO to achieve the high-speed, low-latency, and low-loss communication quality, thereby facilitating the long-distance signal transmission.

In some embodiments, a data stream between the stack structure 30 and the external component 50 may be as shown in FIG. 9. The co-packaged optics 120 of the stack structure 30 receives the optical signal from the external component 50 (corresponding to a block B301) and converts the optical signal into the electrical signal (corresponding to a block B302). Then, the electrical signal is output to the logic chip 130 (corresponding to a block B303). For example, the electrical signal may be transmitted to the base layer (i.e. the first memory layer 110) of the three dimensional memory stack MS through the through substrate via (e.g., the through substrate vias 214 and 314) of each of the memory layers (e.g., the second memory layer 210 and the third memory layer 310) in a portion of the three dimensional memory stack MS corresponding to the co-packaged optics 120, and then transmitted from the base layer to the logic chip 130 through the through substrate via of each of the memory layers in a portion of three-dimensional memory stack MS corresponding to the logic chip 130. In some embodiments, a portion of the electrical signal from the co-packaged optics 120 may be stored directly in the three dimensional memory stack MS. For example, after a portion of the electrical signal is transmitted to the base layer of the three dimensional memory stack MS, the electrical signal is stored in other memory layers of the three dimensional memory stack MS through management and distribution of the base layer.

Next, the logic chip 130 performs the logic computing and the data processing (corresponding to a block B304). In the process of performing the logic computing and the data processing, the logic chip 130 may send a data request (e.g., data writing and/or reading) to the base layer (i.e., the first memory layer 110) of the three dimensional memory stack MS (corresponding to a block B305), and then allocate the data requested by the logic chip 130 to other memory layers of the three dimensional memory stack MS for access through the basic layer (corresponding to a block B306). Afterwards, the computation result of the logic chip 130 is transmitted to the co-packaged optics 120 (corresponding to a block B307). For example, the computation result of the logic chip 130 may be transmitted to the base layer (i.e., the first memory layer 110) of the three dimensional memory stack MS through the portion of the three dimensional memory stack MS corresponding to the logic chip 130, and then transmitted from the base layer (i.e., the first memory layer 110) to the co-packaged optics 120 through the portion of the three dimensional memory stack MS corresponding to the co-packaged optics 120. Then, the electrical signal is converted into the optical signal by the co-packaged optics 120 (corresponding to a block B308), and then output to the external component 50 (corresponding to a block B309). In this way, through the control and management of the basic layer (e.g., the first memory layer 110) of the three dimensional memory stack MS, it is possible to ensure that the three dimensional memory stack MS may work together to achieve the efficient data access and management, thereby improving performance and efficiency of the stack structure 30. In addition, through the configuration of the three dimensional memory stack MS, the storage capacity of the stack structure 30 may be increased, and the space may be effectively utilized, which is conducive to development of miniaturization of an electronic product.

FIG. 8 schematically shows that the three dimensional memory stack MS includes three memory layers, but is not intended to limit the disclosure. The number of memory layers in the three dimensional memory stack MS may be adjusted according to the actual requirements.

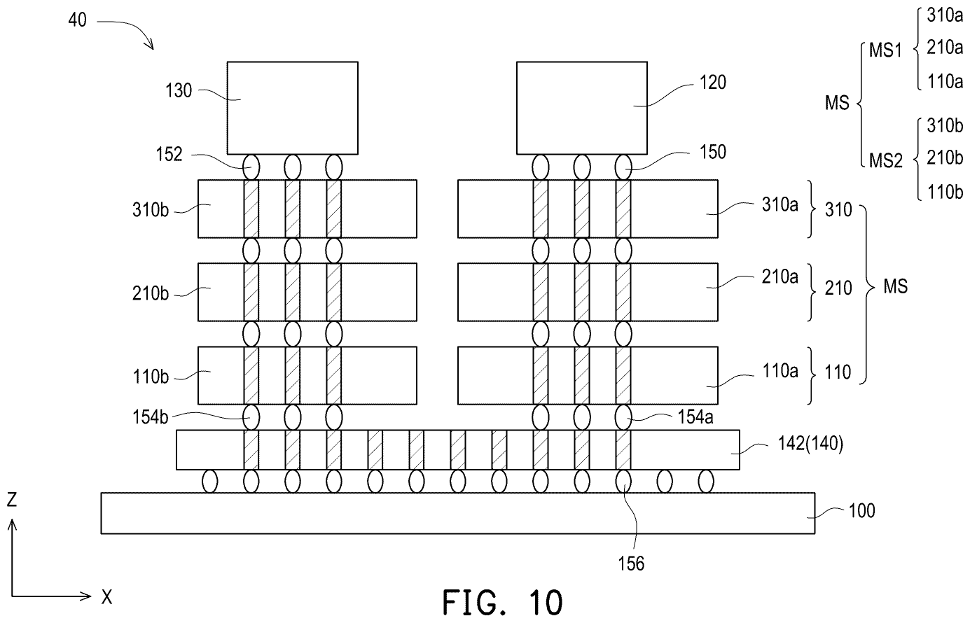

FIG. 10 is a schematic cross-sectional view of a stack structure according to another embodiment of the disclosure. It is noted that some of the reference numerals and descriptions in FIG. 8 will apply to FIG. 10. The same reference numerals will represent the same or similar components and the descriptions of the same technical contents will be omitted. Reference may be made to the above embodiment for the omitted descriptions, which will not be repeated in the following embodiments.

Referring to FIG. 10, a difference between this embodiment and the embodiment in FIG. 8 is that the co-packaged optics 120 and the logic chip 130 of a stack structure 40 are respectively disposed on different memory chips (or different sub-memory stacks) in the three dimensional memory stack MS. For example, the first memory layer 110 of the three dimensional memory stack MS may include the first memory chip 110a and the second memory chip 110b. The first memory chip 110a and the second memory chip 110b are spaced apart in the horizontal direction (e.g., the x direction). The second memory layer 210 of the three dimensional memory stack MS may include the third memory chip 210a and a fourth memory chip 210b. The third memory chip 210a and the fourth memory chip 210b are spaced apart in the horizontal direction (e.g., the x direction). The third memory layer 310 of the three dimensional memory stack MS may include the fifth memory chip 310a and a sixth memory chip 310b. The fifth memory chip 310a and the sixth memory chip 310b are spaced apart in the horizontal direction (e.g., the x direction). In some embodiments, the first memory chip 110a, the third memory chip 210a, and the fifth memory chip 310a may be stacked in the vertical direction z and electrically connected to each other to form a first sub-memory stack MS1. The second memory chip 110b, the fourth memory chip 210b, and the sixth memory chip 310b may be stacked in the vertical direction z and electrically connected to each other to form a second sub-memory stack MS2. The first sub-memory stack MS1 and the second sub-memory stack MS2 are spaced apart in the horizontal direction (e.g. the x-direction). That is to say, the first sub-memory stack MS1 and the second sub-memory stack MS2 do not overlap in the vertical direction z.

In some embodiments, the co-packaged optics 120 may be disposed on the first sub-memory stack MS1 and be physically and electrically connected to the fifth memory chip 310a of the first sub-memory stack MS1 through the conductive connecting member 150. The logic chip 130 may be disposed on the second sub-memory stack MS2 and be physically and electrically connected to the sixth memory chip 310b of the second sub-memory stack MS2 through the conductive connecting member 152. In this way, the co-packaged optics 120 and the first sub-memory stack MS1 as well as the logic chip 130 and the second sub-memory stack MS2 may be designed independently, which is conducive to the modularization and flexible configuration of the system, thereby facilitating the system updates and upgrades to meet different application scenarios.

In some embodiments, the co-packaged optics 120 overlaps the first sub-memory stack MS1 in the vertical direction z, and the logic chip 130 overlaps the second sub-memory stack MS2 in the vertical direction z.

In some embodiments, the first sub-memory stack MS1 and the second sub-memory stack MS2 may be electrically connected to the interposer 140 through conductive connecting members 154a and 154b respectively. That is to say, the first sub-memory stack MS1 may be electrically connected to the second sub-memory stack MS2 through the interposer 140.

In some embodiments, the bottommost memory layer (i.e., the first memory layer 110) of the three dimensional memory stack MS is the base layer of the three dimensional memory stack MS, which may be configured to control and manage the operation of the three dimensional memory stack MS. Therefore, the first memory chip 110a of the first sub-memory stack MS1 may be configured to control and manage operation of the first sub-memory stack MS1, and the second memory chip 110b of the second sub-memory stack MS2 may be configured to control and manage operation of the second sub-memory stack MS2, so that the first memory layer 110 may allocate the data from the logic chip 130 to the memory cells in the memory layers of the sub-memory stack for access, and that other memory layers (e.g., the second memory layer 210 and the third memory layer 310) focus on the data access, so as to achieve the efficient data access and management of the three dimensional memory stack MS.

In some embodiments, the stack structure 40 may perform the high-speed communication with the external component 50 through the co-packaged optics 120, similar to that shown in FIG. 5. However, the stack structure 10 in FIG. 5 is replaced with the stack structure 40 in this embodiment. The co-packaged optics 120 of the stack structure 40 and the co-packaged optics 520 of the external component 50 may perform the optical communication through the optical fibers FO to achieve the high-speed, low-latency, and low-loss communication quality, thereby facilitating the long-distance signal transmission.

In some embodiments, a data stream between the stack structure 40 and the external component 50 may be similar to that shown in FIG. 9. However, when the stack structure 40 transmits the electrical signal to the logic chip 130, the electrical signal is transmitted to the interposer 140 through the through substrate via of each of the memory chips in the first sub-memory stack MS1, and then transmitted from the interposer 140 to the logic chip 130 through the through substrate via of each of the memory chips in the second sub-memory stack MS2. On the contrary, when the stack structure 40 transmits the computation result of the logic chip 130 to the co-packaged optics 120, the computation result is transmitted to the interposer 140 through the second sub-memory stack MS2, then transmitted from the interposer 140 to the co-packaged optics 120 through the first sub-memory stack MS1. In some embodiments, a portion of the electrical signal from the co-packaged optics 120 may be stored directly in the three dimensional memory stack MS. For example, after a portion of the electrical signal is transmitted to the base layer (e.g., the first memory chip 110a or the second memory chip 110b) of the three dimensional memory stack MS, the electrical signal is stored in other memory layers of the three dimensional memory stack MS through the management and distribution of the base layer.

It should be understood that FIG. 10 schematically shows one co-packaged optics 120 disposed on the first sub-memory stack MS1 and one logic chip 130 disposed on the second sub-memory stack MS2, but is not intended to limit the disclosure. One or more co-packaged optics 120 and/or one or more logic chips 130 may be respectively disposed on the first sub-memory stack MS1 and the second sub-memory stack MS2 according to the actual requirements. In addition, the number of sub-memory stacks and the number of included memory layers thereof in the three dimensional memory stack MS may be adjusted according to the actual requirements, and the disclosure is not limited thereto.

Based on the above, the stack structure in the disclosure includes the logic chip and the co-packaged optics stacked on the memory layer, which may shorten the distance of data transmission, thereby improving the data access speed and the overall performance and reducing the power consumption. In addition, tightly stacked on the memory layer, the logic chip and the co-packaged optics may facilitate the development of the miniaturization of the product.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A stack structure, comprising:
a substrate;
a first memory layer disposed over the substrate;
a logic chip disposed on the first memory layer and electrically connected to the first memory layer; and
a co-packaged optics disposed on the first memory layer and electrically connected to the first memory layer.

2. The stack structure according to claim 1, wherein the logic chip and the co-packaged optics are disposed side by side in a horizontal direction.

3. The stack structure according to claim 1, wherein the first memory layer comprises a single memory chip, and the co-packaged optics and the logic chip are disposed on the memory chip, and are electrically connected to the memory chip.

4. The stack structure according to claim 3, wherein a width of the memory chip is greater than a width of the co-packaged optics and a width of the logic chip.

5. The stack structure according to claim 1, wherein the first memory layer comprises a first memory chip and a second memory chip, and the first memory chip and the second memory chip are spaced apart in a horizontal direction,
wherein the co-packaged optics is disposed on the first memory chip, and is electrically connected to the first memory chip, and the logic chip is disposed on the second memory chip, and is electrically connected to the second memory chip.

6. The stack structure according to claim 1, further comprising:
a second memory layer disposed on the first memory layer, wherein the second memory layer is located between the first memory layer and the co-packaged optics, and the co-packaged optics is electrically connected to the first memory layer through the second memory layer.

7. The stack structure according to claim 6, wherein the first memory layer is configured to receive a data request from the logic chip, and control and manage access to a memory cell of the second memory layer.

8. The stack structure according to claim 7, wherein
the co-packaged optics is configured to receive an optical signal from an external component and convert the optical signal into an electrical signal,
the electrical signal is transmitted to the logic chip through the first memory layer and the second memory layer,
the logic chip is configured to perform logic computing and data processing, wherein in a process of performing the logic computing and the data processing, the logic chip sends the data request to the first memory layer, and the first memory layer allocates data to the second memory layer for access, and
a computation result of the logic chip is transmitted to the co-packaged optics through the first memory layer.

9. The stack structure according to claim 6, wherein the first memory layer comprises a first memory chip and a second memory chip, and the first memory chip and the second memory chip are spaced apart in a horizontal direction,
wherein the second memory layer comprises a third memory chip and a fourth memory chip, the first memory chip and the second memory chip are spaced apart in the horizontal direction, the first memory chip and the third memory chip are stacked in a vertical direction, and the second memory chip and the fourth memory chip are stacked in the vertical direction, wherein the horizontal direction is perpendicular to the vertical direction.

10. The stack structure according to claim 9, wherein the co-packaged optics overlaps the first memory chip and the third memory chip in the vertical direction, and the logic chip overlaps the second memory chip and the fourth memory chip in the vertical direction.

11. The stack structure according to claim 1, further comprising:
an interposer disposed between the substrate and the first memory layer.

12. The stack structure according to claim 11, wherein the co-packaged optics is electrically connected to the interposer through a through substrate via of the first memory layer.

13. The stack structure according to claim 1, wherein the first memory layer comprises a static random-access memory.

14. The stack structure according to claim 1, wherein
the co-packaged optics is configured to receive an optical signal from an external component and convert the optical signal into an electrical signal,
the electrical signal is transmitted to the logic chip through the first memory layer,
the logic chip is configured to perform logic computing and data processing, wherein in a process of performing the logic computing and the data processing, data is written from the logic chip to the first memory layer or read from the first memory layer to the logic chip, and
a computation result of the logic chip is transmitted to the co-packaged optics through the first memory layer.
